(19) United States
(12) Patent Application Publication
(10) Pub. No.: US 2024/0332209 A1
(43) Pub. Date: Oct. 3, 2024

(54) METHOD FOR FORMING A SHIELDING LAYER ON A SEMICONDUCTOR DEVICE

(71) Applicant: STATS ChipPAC Pte. Ltd., Singapore (SG)

(72) Inventors: JiSik MOON, Incheon (KR); KyoWang KOO, Incheon (KR); HyunSeok PARK, Gyeonggi-do (KR)

(21) Appl. No.: 18/603,185

(22) Filed: Mar. 12, 2024

(30) Foreign Application Priority Data
Mar. 29, 2023 (CN) 202310326465.5

(51) Int. Cl. H01L 23/552; H01L 21/683; H01L 21/78; H01L 23/31; H01L 23/498; H01L 25/16

(52) U.S. Cl. CPC H01L 23/552; H01L 21/6836; H01L 21/78; H01L 23/3107; H01L 23/49816; H01L 25/16

(57) ABSTRACT

A method for forming a shielding layer to a semiconductor device, wherein the semiconductor device comprises a substrate, one or more electronic components on a front surface of the substrate, an encapsulant layer on the front surface of the substrate that covers the one or more electronic components and one or more connectors on a back surface of the substrate, the method comprising: applying a coating layer onto the back surface of the substrate to cover the one or more connectors; attaching the coating layer onto a tape to load the semiconductor device to the tape, wherein the attachment between the coating layer and the tape is stronger than the attachment between the coating layer and the back surface of the substrate as well as the one or more connectors; forming the shielding layer onto the encapsulant layer to cover the one or more electronic components; and unloading the semiconductor device from the tape, wherein the coating layer is left on the tape.

### TECHNICAL FIELD

The present application generally relates to semiconductor packaging technology, and more particularly, to a method for forming a shielding layer on a semiconductor device.

### BACKGROUND OF THE INVENTION

The semiconductor industry is constantly faced with complex integration challenges as consumers want their electronic products to be lighter, smaller and have higher performance with more and more functionalities. One of the solutions is System-in-Package (SiP). SiP is a functional electronic system or sub-system that includes in a single package two or more heterogeneous semiconductor dice or other passive devices, such as a logic chip, a memory, integrated passive devices (IPD), RF filters, sensors, heat sinks, or antennas. However, there may be interferences such as electromagnetic interference (EMI) between these devices and from the external environment.

A semiconductor device may be provided with a metal cover or a uniformly spread coating around its outer surface as a shielding layer for EMI reduction. If the semiconductor device includes connectors that are used for connecting the semiconductor device to other components (e.g., solder balls), the connectors should be protected before the shielding layer is formed on the semiconductor device, otherwise they may be contaminated by the material of the shielding layer.

Typically, the connectors of the semiconductor device may be protected by paste or tapes, which may be applied to the connectors before the shielding layer is formed onto the semiconductor device. These approaches may need complicated processes (e.g., UV irradiation, oven cure etc.), or may damage the connectors. Furthermore, in some cases where the connectors are relatively large, there may be no applicable approaches for protecting the connectors because tapes may peel off due to the large connectors.

Therefore, a need exists for a method for forming a shielding layer on a semiconductor device.

### SUMMARY OF THE INVENTION

An objective of the present application is to provide a method for forming a shielding layer on a semiconductor device.

In an aspect of the present application, a method for forming a shielding layer to a semiconductor device is provided. The semiconductor device comprises a substrate, one or more electronic components on a front surface of the substrate, an encapsulant layer on the front surface of the substrate that covers the one or more electronic components and one or more connectors on a back surface of the substrate. The method comprises: applying a coating layer onto the back surface of the substrate to cover the one or more connectors; attaching the coating layer onto a tape to load the semiconductor device to the tape, wherein the attachment between the coating layer and the tape is stronger than the attachment between the coating layer and the back surface of the substrate as well as the one or more connectors; forming the shielding layer onto the encapsulant layer to cover the one or more electronic components; and unloading the semiconductor device from the tape, wherein the coating layer is left on the tape.

In another aspect of the present application, a semiconductor device is provided, which may be formed using the method provided in the above aspect of the present application.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 is a sectional view showing a semiconductor device according to an embodiment of the present application.

FIG. 2 is a flow chart of a method for forming a shielding layer to the semiconductor device as shown in FIG. 1 according to an embodiment of the present application.

FIG. 3A to FIG. 3D are sectional views showing various steps of the method shown in FIG. 2 according to an embodiment of the present application.

FIG. 4A to FIG. 4C are sectional views showing an exemplary process for applying the coating layer to the semiconductor device, according to an embodiment of the present application.

FIG. 5A to 5E are sectional views showing a process for forming semiconductor devices which are singulated from a device array according to an embodiment of the present application.

FIGS. 6A and 6B are sectional views respectively showing a semiconductor device, before and after a coating layer is applied onto the semiconductor device, according to another embodiment of the present application.

FIGS. 7A and 7B are sectional views respectively showing a semiconductor device, before and after a coating layer is applied onto the semiconductor device, according to a further embodiment of the present application.

FIGS. 8A and 8B are sectional views respectively showing a semiconductor device, before and after a coating layer is applied onto the semiconductor device, according to yet a further embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for case of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

In order to resolve at least one of the problems of the conventional processes for forming shielding layers on semiconductor devices, the inventors of the present applications provided a method for applying protective coating layers on substrates of semiconductor devices that can cover connectors of the substrates. In this way, the connectors may not be exposed during the processes for forming shielding layers and thus protected from contaminations as well as metal burrs which are undesired at the edges of the shielding layers.

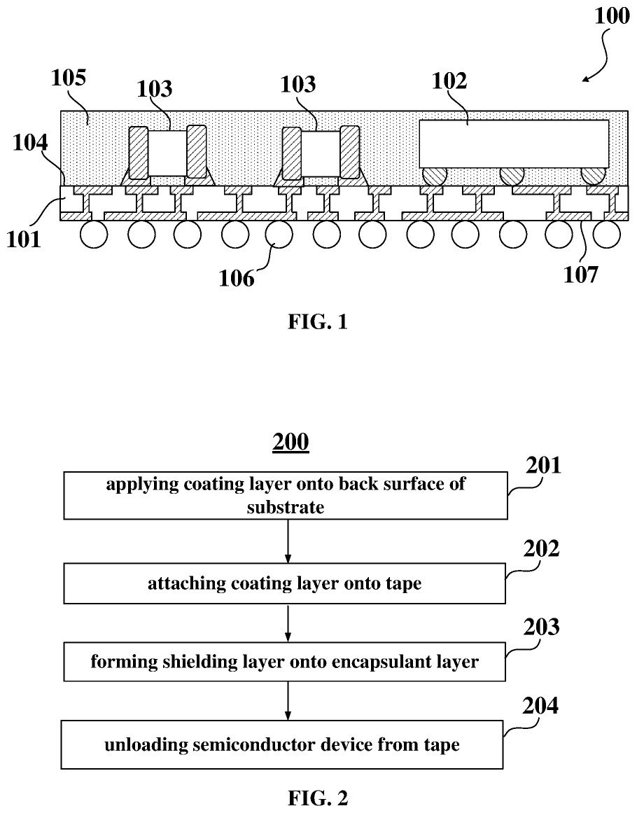

FIG. 1 is a sectional view showing a semiconductor device 100 according to an embodiment of the present application.

As shown in FIG. 1, the semiconductor device 100 includes a substrate 101 such as a printed circuit board (PCB) or an interposer. One or more electronic components, such as one or more additional semiconductor dice 102 or one or more passive devices 103 (e.g., capacitors or resistors) can be mounted on a front surface 104 of the substrate 101. An encapsulant layer 105 is also formed on the front surface 104 of the substrate 101, to cover the one or more electronic components 102 and 103 and provide protection for them. Further, one or more connectors 106 are formed on a back surface 107 of the substrate 101, to electrically connect the semiconductor device 100 to an external component or device, for example, to another substrate such as a PCB or another semiconductor device or package. In this embodiment, the connectors 106 include multiple solder balls.

In some embodiments, the substrate 101 may be a PCB, a laminate interposer, a strip interposer, a leadframe, or another suitable substrate. The substrate 101 may include one or more insulating or passivation layers, one or more conductive vias formed through the insulating layers, and one or more conductive layers formed over or between the insulating layers. The substrate 101 may include one or more laminated layers of polytetrafluoroethylene pre-impregnated, FR-4, FR-1, CEM-1, or CEM-3 with a combination of phenolic cotton paper, epoxy, resin, woven glass, matte glass, polyester, or other reinforcement fibers or fabrics. The substrate 101 may also be a multi-layer flexible laminate, ceramic, copper clad laminate, glass, or semiconductor wafer including an active surface containing one or more transistors, diodes, and other circuit elements to implement analog circuits or digital circuits. The substrate 101 may include one or more electrically conductive layers or redistribution layers (RDL) formed using sputtering, electrolytic plating, electroless plating, or other suitable deposition process. The conductive layers may be one or more layers of Al, Cu, Sn, Ni, Au, Ag, Ti, W, or other suitable electrically conductive material. In some embodiments, one or more conductive patterns may be exposed from the surface of the substrate 101, and subsequently connected with solder balls or the like for subsequent mounting or connecting of other components or devices.

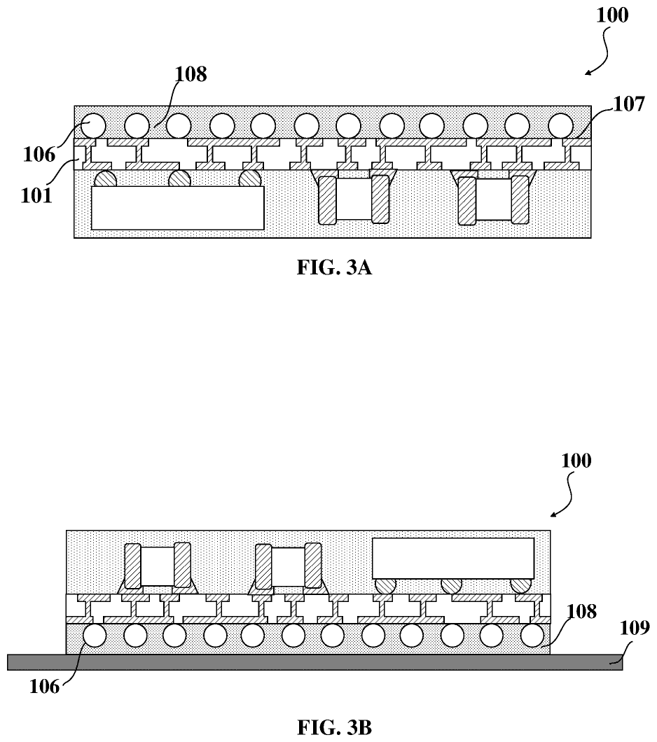

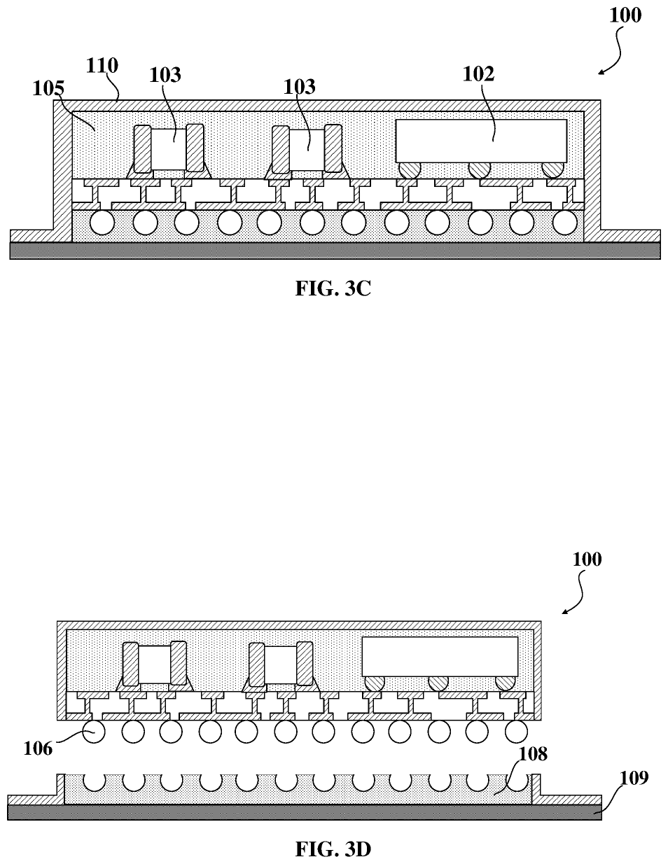

FIG. 2 is a flow chart of a method 200 for forming a shielding layer to the semiconductor device 100 shown in FIG. 1, according to an embodiment of the present application. FIG. 3A to FIG. 3D are sectional views showing various steps of the method 200 shown in FIG. 2, according to an embodiment of the present application. In the following, the method may be elaborated with reference to FIG. 2 and FIGS. 3A to 3D.

The method 200 starts with Step 201, a coating layer is applied onto a back surface of a substrate. In particular, as shown in FIG. 3A, the semiconductor device 100 can be reversed and placed on a carrier (not shown) such as a platform, with the back surface 107 of the substrate 101 as well as solder balls 106 formed on the back surface 107 facing upward. A coating layer 108 is then applied onto the back surface 107 of the substrate 101, which covers the solder balls 106 and the other regions of the back surface 107. In some embodiments, the coating layer 108 may be a resin material, such as a silicon type material, a liquid type polymer coating material with silicon elastomer, a resin material including silicon. Although the back surface 107 is uneven due to the solder balls 106, the coating layer 108 may reduce or eliminate the unevenness of the back surface 107 after it is formed on the back surface 107.

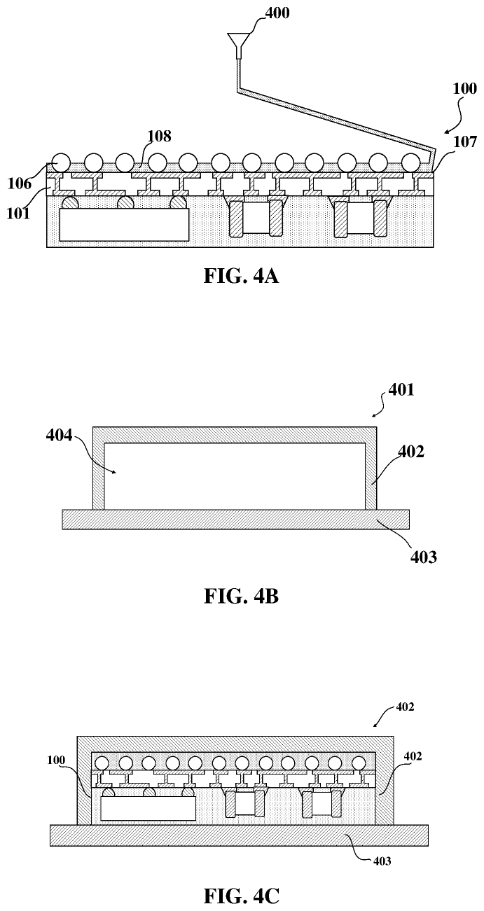

Various methods can be used to form the coating layer 108 on the substrate 101. FIG. 4A to FIG. 4C are sectional views showing an exemplary process for applying the coating layer to the semiconductor device, according to an embodiment of the present application. The process is a compression molding based process. However, it can be appreciated that other processes such as injection molding process can be used to form the coating layer.

As shown in FIG. 4A, a nozzle 400 can be positioned above the back surface 107 of the substrate 101 of the semiconductor device 100. A resin material or other similar materials can be applied to the back surface 107 of the substrate 101 by spraying or extruding through the nozzle 400. The semiconductor device 100 (placed on a carrier) and the nozzle 400 can be moved back and forth relative to each other, so that the resin material can be deposited from the nozzle 400 onto the whole back surface 107 of the substrate 101 layer by layer. Although the resin material is gradually deposited onto the back surface 107 of the substrate 101, it may still not be uniformly formed across the back surface 107, i.e., the top surface of the resin material may be uneven. For example, there may be redundant resin material formed around the periphery of the semiconductor device 100, but less resin material at the central position of the semiconductor device 100.

After a sufficient amount of the resin material is deposited on the substrate 101, the resin material may be further processed to develop a better and more uniform shape. As shown in FIG. 4B, a chase 401 can be provided which may be preformed with a desired shape and size for accommodating the semiconductor device with the coating layer. For example, the chase 401 may include an upper portion 402 and a lower portion 403, and a cavity 404 can be formed between the upper portion 402 and the lower portion 403 with the desired shape and size. As shown in FIG. 4C, the semiconductor device 100 with the resin material can be positioned into the cavity 404 of the chase 401. Subsequently, the upper and lower portions 402 and 403 may be pressed against each other, so that the resin material on the back surface 107 of the substrate 101 can be compressed and molded to the desired shape. For example, the top surface of the resin material can be planarized and some redundant resin material (if any) on the semiconductor device 100 can be removed off. Therefore, an even coating layer 108 can be formed on the back surface 107 of the substrate 101.

Referring back to FIG. 2, at Step 202, the coating layer is attached onto a tape, to load the semiconductor device to the tape. In particular, as shown in FIG. 3B, after the coating layer 108 is applied onto the back surface 107 of the substrate 101, the semiconductor device 100 can be placed onto a tape 109, with the coating layer 108 in contact with the tape 109. The attachment between the coating layer 108 and the tape 109 may be stronger than the attachment between the coating layer 108 and the back surface 107 of the substrate 101 as well as the one or more connectors 106, so that the coating layer 108 can be left on the tape 109 after a shielding layer is formed on the semiconductor device 100 and the semiconductor device 100 is lifted off the tape 109, which will be discussed in detail below. In some embodiments, the tape 109 may be a polyimide tape or any other suitable tapes. In some embodiments, the tape 109 may be further placed on a carrier such as a platform or a plate such that it can hold the semiconductor device 100 firmly during the subsequent processed performed on the semiconductor device 100.

Next, as shown in FIG. 2, at Step 203, a shielding layer is formed onto the encapsulant layer, which covers the one or more electronic components of the semiconductor device. In particular, as shown in FIG. 3C, a shielding layer 110 is formed onto the encapsulant layer 105, which can cover the one or more electronic components 102 and 103, to shield EMI induced to (or generated by) the electronic components 102 and 103 encapsulated by the encapsulant layer 105. The shielding layer 110 may be a conductive material such as a metal material or alloy. In some embodiments, the shielding layer 110 may be formed using a sputtering process, and the shielding material may not only be deposited over the encapsulant layer 105 but also over the tape that is not covered by the semiconductor device 100, thereby forming a continuous interface from the tape to the substrate 101 through the coating layer.

Afterwards, as shown in FIG. 2, at Step 204, the semiconductor device is unloaded from the tape. In particular, as shown in FIG. 3D, after the shielding layer 110 is formed onto the encapsulant layer 105, the semiconductor device 100 is unloaded from the tape 109. As discussed above, the attachment between the coating layer 108 and the tape 109 may be stronger than the attachment between the coating layer 108 and the back surface 107 of the substrate 101 as well as the one or more connectors 106, and therefore the coating layer 108 is left on the tape 109 and may not be removed from the tape along with the semiconductor device 100.

As such, through applying a coating layer 108 to cover the connectors 106 on the back surface 107 of the substrate prior to forming the shielding layer 110 onto the semiconductor device 100, the connectors 106 are prevented from being connected with and contaminated by the material of the shielding layer. Therefore, defects such as shorts and metal burrs between the connectors 106 and the shielding layer can be avoided and at least reduced significantly.

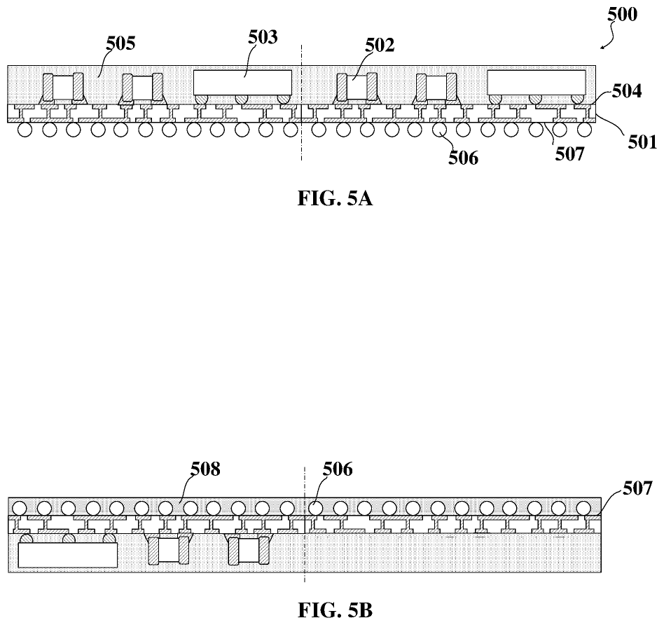

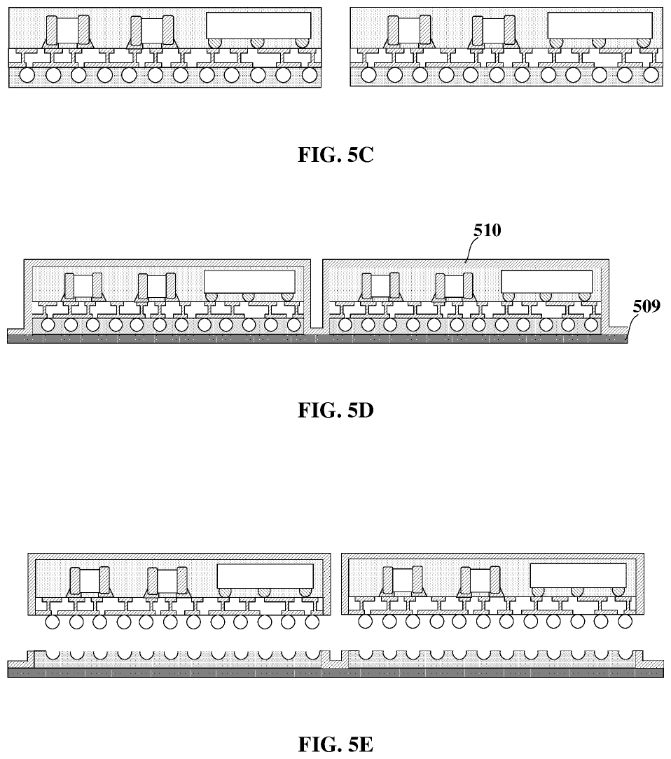

In some embodiments, the semiconductor device such as the semiconductor device 100 as discussed above can be singulated from a device array. A coating layer can be formed on the device array, rather than on the separated semiconductor devices, and thus the efficiency of the process can be improved. FIG. 5A to 5E are sectional views showing a process for forming semiconductor devices which are singulated from a device array according to an embodiment of the present application.

As shown in FIG. 5A, the device array 500 includes two semiconductor devices, as schematically indicated by the dashed line, for example, including two semiconductor devices 100 as shown in FIG. 1. However, those skilled in the art can understand that a device array may include any number of semiconductor devices, for example, including 3, 4, 5 or more semiconductor devices. A plurality sets of electronic components 502 and 503 can be mounted on a front surface 504 of a substrate 501 in a specific arrangement, with each set of electronic components 502 and 503 corresponding to a semiconductor device of the device array 500. An encapsulant layer 505 can be formed on the front surface 504 of the substrate 501 to cover and protect the plurality sets of electronic components 502 and 503. Further, a plurality sets of connectors 506 can be formed on a back surface 507 of the substrate 501, with each set of connectors 506 corresponding to a semiconductor device of the device array. As such, the two semiconductor devices of the device array are formed, and may be singulated later from the device array along the dashed line later as discussed below.

Next, as shown in FIG. 5B, the device array 500 may be reversed and placed on a carrier (not shown), with a back surface 507 of the substrate 501 as well as the connectors 506 on the back surface 507 are facing upward. A coating layer 508 is then applied onto the back surface 507 of the substrate 501, therefore the connectors 506 are covered by the coating layer 508. The coating layer 108 may be applied through the process as shown in FIG. 4 and thus not elaborated herein. Further, as shown in FIG. 5C, after the coating layer 508 is applied onto the back surface 507 of the substrate 501, the two semiconductor devices of the device array 500 are singulated from each other. Afterwards, the semiconductor devices singulated from the device array 500 can be loaded onto a tape 509, a shielding layer 510 can be formed on the semiconductor devices, and then each semiconductor device can be unloaded from the tape 509, as shown in FIG. 5D and FIG. 5E. These steps are similar as the steps shown in FIG. 3B to 3D. Similarly, the shielding material deposited on the tape 509, including a portion between the two semiconductor devices and the other portions around the two semiconductor devices, can be adhered to the tape 509 and prevented from lifting off with the semiconductor devices. Furthermore, the coating layer 508 under the semiconductor devices cannot be removed off the tape 509. Thus, the connectors of the semiconductor devices 508 can be well protected from being connected with the shielding layer on the lateral surfaces of the semiconductor devices.

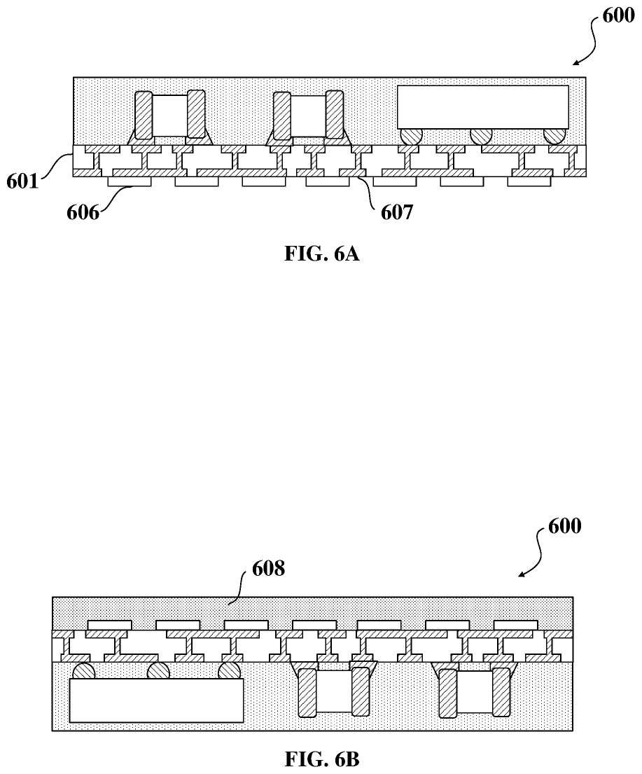

Various forms of connectors formed on semiconductor devices can be protected by the coating layers and prevented from being connected to shielding layers of the semiconductor devices due to metal burrs. FIGS. 6A and 6B, 7A and 7B, and 8A and 8B provide some other examples of semiconductor devices that are suitable for implementing the coating process according to some embodiments of the present application.

FIGS. 6A and 6B are sectional views respectively showing a semiconductor device 600, before and after a coating layer is applied onto the semiconductor device, according to another embodiment of the present application.

As shown in FIG. 6A, the semiconductor device 600 includes components generally similar as the semiconductor device 100 shown in FIG. 1. Differently, the semiconductor device 600 includes conductive patterns 606 on a back surface 607 of a substrate 601 of the semiconductor device 600 as connectors. For example, the conductive patterns 606 can be formed through electroplating on the back surface 607 of the substrate 601. As shown in FIG. 6B, a coating layer 608 can be applied onto the back surface 607 of the substrate 601, to cover and protect the conductive patterns 606. Steps similar as those shown in FIGS. 3B to 3D can be performed to the semiconductor device 600 to form a shielding layer on the semiconductor device 600 without formation of metal burrs.

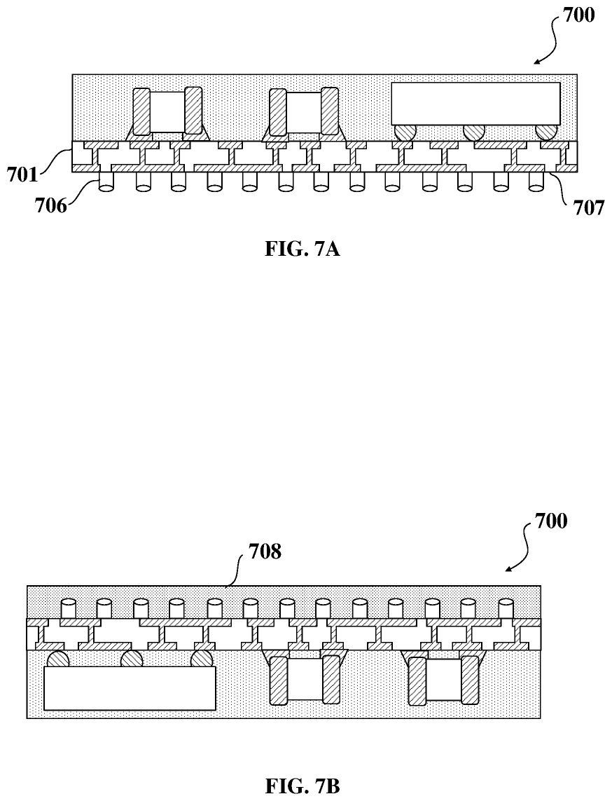

FIGS. 7A and 7B are sectional views respectively showing a semiconductor device 700, before and after a coating layer is applied onto the semiconductor device, according to a further embodiment of the present application.

As shown in FIG. 7A, the semiconductor device 700 includes components generally similar as the semiconductor device 100 as shown in FIG. 1. Differently, the semiconductor device 700 includes one or more conductive posts on a back surface 707 of a substrate 701 of the semiconductor device 700 as connectors. As shown in FIG. 7B, a coating layer 708 can be applied onto the back surface 707 of the substrate 701, to cover and protect the conductive posts 706. Steps similar as those shown in FIGS. 3B to 3D can be performed to the semiconductor device 700 to form a shielding layer on the semiconductor device 700 without formation of metal burrs.

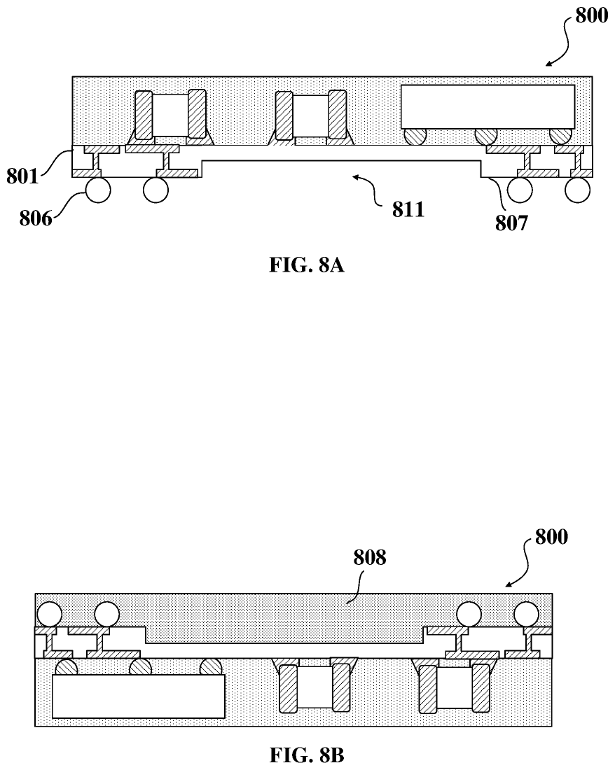

FIGS. 8A and 8B are sectional views respectively showing a semiconductor device 800, before and after a coating layer is applied onto the semiconductor device, according to yet a further embodiment of the present application.

As shown in FIG. 8A, the semiconductor device 800 includes components generally similar as the semiconductor device 100 as shown in FIG. 1. Differently, a back surface 807 of a substrate 801 of the semiconductor device 800 includes a cavity 811. That is to say, the back surface 807 is uneven, other than solder balls formed on the back surface 807. As shown in FIG. 8B, when a coating layer 808 is applied onto the semiconductor device 800, the coating layer 808 may fill in the cavity 811 of the back surface 807 of the substrate 801 and gaps between the connectors. Steps similar as those shown in FIGS. 3B to 3D can be performed to the semiconductor device 800 to form a shielding layer on the semiconductor device 800 without formation of metal burrs.

As can be seen, the approach of forming a coating layer to protect connectors prior to forming a shielding layer as disclosed in the present application may apply to a semiconductor device with various semiconductor devices with different connectors and different shaped substrates.

Compared with the prior approaches for protecting the connectors, such as printing paste or applying a tape onto the connectors, the approach as disclosed with reference to the embodiments of the present application may form an even coating layer on the semiconductor device to cover the connectors regardless the size or arrangement of the connectors, therefore a risk of damaging the connectors and forming undesired metal burrs at edges of shielding layers can be significantly reduced. In addition, the approach according to the embodiments of the present application may not need complicated processes such as UV irradiation or oven cure, therefore the cost can be reduced.

The discussion herein included numerous illustrative figures that showed various portions of a method for forming a shielding layer on a semiconductor device, and a semiconductor device with such formed shielding layer. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming a shielding layer to a semiconductor device, wherein the semiconductor device comprises a substrate, one or more electronic components on a front surface of the substrate, an encapsulant layer on the front surface of the substrate that covers the one or more electronic components and one or more connectors on a back surface of the substrate, the method comprising:
applying a coating layer onto the back surface of the substrate to cover the one or more connectors;
attaching the coating layer onto a tape to load the semiconductor device to the tape, wherein the attachment between the coating layer and the tape is stronger than the attachment between the coating layer and the back surface of the substrate as well as the one or more connectors;
forming the shielding layer onto the encapsulant layer to cover the one or more electronic components; and
unloading the semiconductor device from the tape, wherein the coating layer is left on the tape.

2. The method for claim 1, wherein applying a coating layer onto the back surface of the substrate includes spraying a resin material onto the back surface of the substrate.

3. The method for claim 2, further comprising molding the resin material on the back surface of the substrate by positioning a chase that has a desired shape onto the resin material on the back surface of the substrate.

4. The method for claim 1, wherein the coating layer comprises a silicon type material, a liquid type polymer coating material with silicon elastomer, or a resin material including silicon.

5. The method for claim 1, wherein the one or more connectors comprises solder balls, conductive patterns, conductive posts, or a combination thereof.

6. The method for claim 1, wherein the back surface of the substrate includes a cavity, and applying a coating layer onto the back surface of the substrate includes filling the cavity with the coating layer.

7. The method for claim 1, wherein the semiconductor device is singulated from a device array.

8. The method for claim 7, wherein applying a coating layer onto the back surface of the substrate include applying the coating layer to the device array.

9. The method for claim 8, wherein the semiconductor device is singulated from the device array after applying the coating layer to the device array.

10. A semiconductor device formed according to a method that includes the following steps:
applying a coating layer onto a back surface of a substrate to cover one or more connectors on the back surface of the substrate;
attaching the coating layer onto a tape to load the semiconductor device to the tape, wherein the attachment between the coating layer and the tape is stronger than the attachment between the coating layer and the back surface of the substrate as well as the one or more connectors;
forming a shielding layer onto an encapsulant layer to cover one or more electronic components on a front surface of the substrate; and
unloading the semiconductor device from the tape, wherein the coating layer is left on the tape.
